(19) United States
(12) Patent Application Publication
(10) Pub. No.: US 2025/0101577 A1
(43) Pub. Date: Mar. 27, 2025

(54) Microwave Capillary Nanodiamond Reactor

(71) Applicant: Board of Trustees of Michigan State University, East Lansing, MI (US)

(72) Inventors: Tanvi NIKHAR, Lansing, MI (US); Sergey V. BARYSHEV, Okemos, MI (US)

(73) Assignee: Board of Trustees of Michigan State University, East Lansing, MI (US)

(21) Appl. No.: 18/890,897

(22) Filed: Sep. 20, 2024

Related U.S. Application Data
(60) Provisional application No. 63/539,647, filed on Sep. 21, 2023.

(51) Int. Cl. C23C 16/27; C23C 16/511; H01J 37/32

(52) U.S. Cl. CPC C23C 16/274; C23C 16/511; H01J 37/32192; H01J 37/32715; H01J 2237/202; H01J 2237/3321

(57) ABSTRACT

A microwave capillary nanodiamond reactor assembly, and methods of making and using same, are provided. In another aspect, a reactor and method use less than 100 W of microwave power within a cavity to create a plasma therein, so a substrate or workpiece is placed in a cool plasma zone of about 350-400° C., while growing diamond on the workpiece in a low temperature synthesis manner. In another aspect, a workpiece is moved within a diamond-growing reactor while plasma is in a plasma cavity of the reactor. Furthermore, an aspect of the present reactor and method moves a plasma generating head of a reactor relative to a workpiece while the workpiece is in the reactor.

### CROSS-REFERENCE TO RELATED APPLICATION

This application claims priority to U.S. Provisional Application Ser. No. 63/539,647, filed on Sep. 21, 2023, which is incorporated by reference herein.

### BACKGROUND AND SUMMARY

The present disclosure generally pertains to nanodiamond reactors and more particularly to a microwave capillary nanodiamond reactor.

It is known to use chemical vapor deposition (“CVD”) reactors for nanodiamond deposition. For example, commonly owned U.S. Pat. No. 9,890,457 is entitled “Microwave Plasma Reactors” and issued to Asmussen, et al. on Feb. 13, 2018. This patent is incorporated by reference herein. While this patent is a significant advancement in the industry, further improvements are desired.

Other conventional nanodiamond CVD reactors are discussed in Kumar, A., et al., “Formation of Nanodiamonds at Near-Ambient Conditions via Microplasma Dissociation of Ethanol Vapour,” Nature Communications, 4:2618 (Oct. 21, 2013), and Hemanwan, K., et al., “Diamond Synthesis at Atmospheric Pressure by Microwave Capillary Plasma Chemical Vapor Deposition,” Appl. Phys. Lett., 107, 181901 (Nov. 2, 2015). Traditional canonical CVD reactors are connected to a high power magnetron through a rigid waveguide network, and the power levels required for diamond synthesis are approximately 1 KW. Since the substrate is in direct contact with the outer hot plasma zone, diamond deposition can only be formed on a substrate having a melting point well in excess of 1,000° C. Such conventional CVD reactors are very large, stationary and expensive to manufacture and use. Furthermore, there is typically no ability to reposition workpieces relative to plasma within traditional nanodiamond CVD reactors. Additionally, structural and electrical properties of ultra-nano-crystalline diamond films grown in a microwave plasma assisted CVD reactor are discussed in Nikhar, T. and Baryshev, S., et al., “Dynamic Graphitization of Ultra-Nano-Crystalline Diamond and its Effects on Material Resistivity,” J. Appl. Phys., 128, 235305 (Dec. 21, 2020).

In accordance with the present invention, a microwave capillary nanodiamond reactor assembly, and methods of making and using same, are provided. In another aspect, a reactor and method use less than 100 W of microwave power within a cavity to create a plasma therein, so a substrate or workpiece is placed in a cool plasma zone of about 350-400° C., while growing diamond on the workpiece in a low temperature synthesis manner. A further aspect of the present reactor assembly includes a flow-through reactor having a hollow tube intersecting a plasma cavity, connected to a microwave power supply and reaction gas tank, with a workpiece holder movable along the tube.

In another aspect, a workpiece is moved within a diamond-growing reactor while plasma is in a plasma cavity of the reactor. Furthermore, an aspect of the present reactor and method moves a plasma generating head of a reactor relative to a workpiece while the workpiece is in the reactor. Yet another aspect employs a method of using a diamond reactor including depositing a first layer within a microwave powered plasma directly on a substrate, depositing at least a second layer within the microwave powered plasma onto the first layer, at least one of the layers being diamond and at least one of the layers being a different material (for example, sp3 or sp2 hybridization, or a mixture thereof), such as but not being limited to a buffer material or a graphite material; all of the layers being deposited while the substrate remains in the plasma, and/or outside the plasma, and/or while the reactor is operating.

The present reactor is advantageous over traditional systems. For example, the present reactor and method beneficially allow for changes in diamond growth on the workpiece by moving the workpiece-holder in the plasma and tube. The present reactor is well suited for the deposition of diamond films on polymeric substrates for use in biomedical implants, bionic devices, and electrochemical devices, due to the lower manufacturing temperatures. The present reactor (excluding a gas tank and a microwave power supply) has a maximum exterior dimension no greater than 20 cm³ as compared to conventional CVD reactors greater than 1 m³, thereby allowing the present reactor to be portable and/or useable in an additive manufacturing machine such as one having a moveable plasma head on a gantry, while accommodating an exposed substrate surface of at least 1 cm². Additional advantages and features will be disclosed in the following description and appended claims, taken in conjunction with the accompanying drawings.

### BRIEF DESCRIPTION OF THE DRAWINGS

FIG. 1 is a perspective view showing the present reactor assembly;

FIG. 2 is a diagrammatic side view showing a reactor of the present reactor assembly;

FIG. 3 is a diagrammatic side view showing the present reactor assembly;

FIG. 4 is an enlarged cross-sectional view showing the reactor of the present reactor assembly;

FIG. 5 is a diagrammatic perspective view showing an alternate embodiment of the present reactor assembly;

FIG. 6 is an exaggerated side view showing a first alternate embodiment of a layered substrate employed with the present reactor assembly; and

FIG. 7 is an exaggerated side view showing a second alternate embodiment of a layered substrate employed with the present reactor assembly.

### DETAILED DESCRIPTION

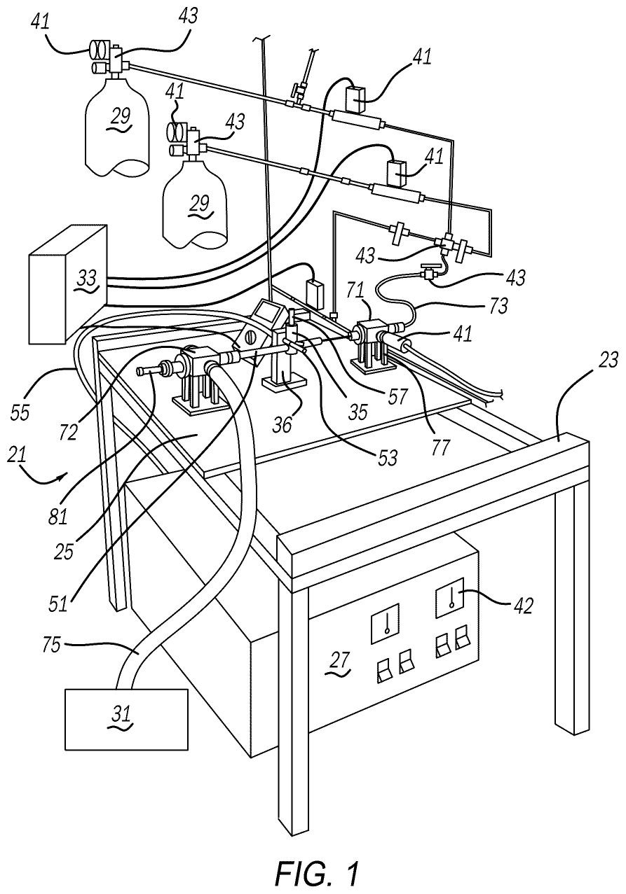

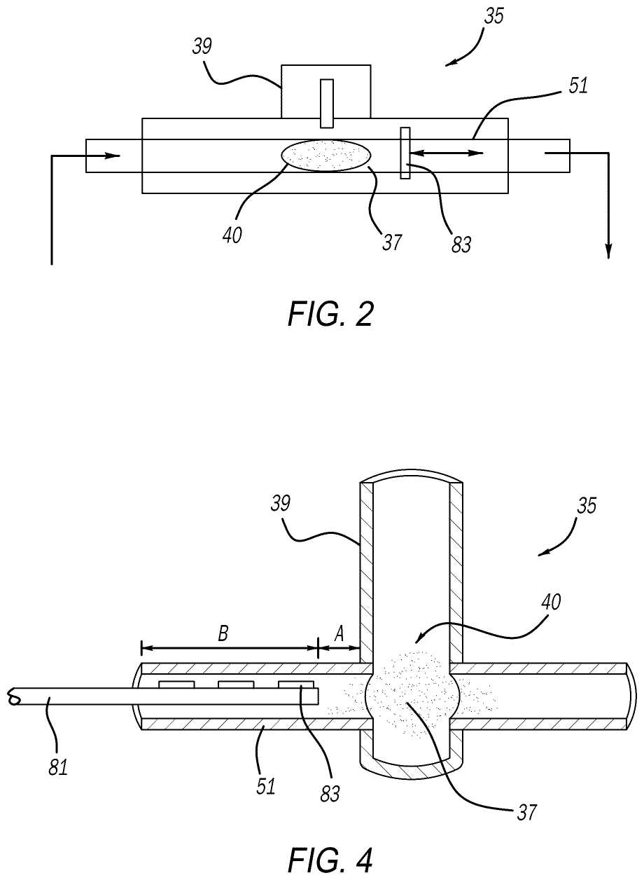

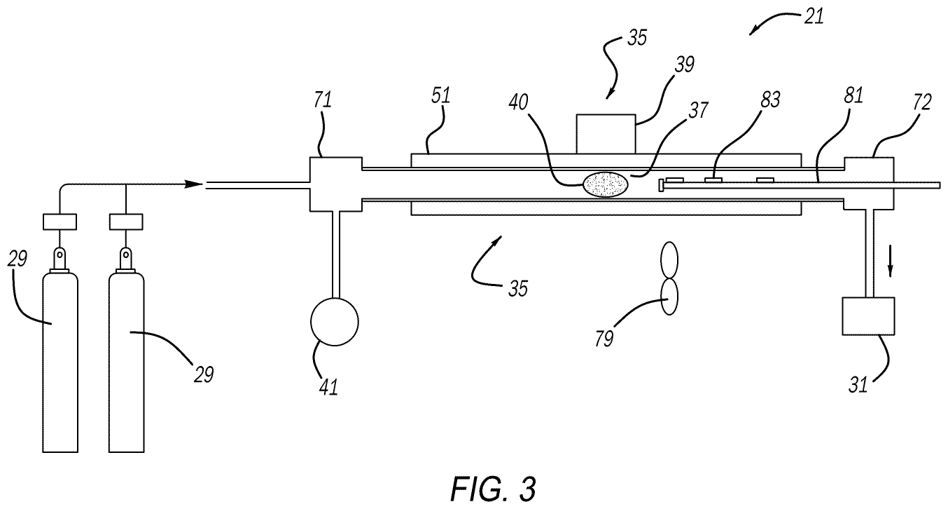

A preferred embodiment of a microwave capillary nanodiamond reactor assembly 21 is illustrated in FIGS. 1-4. Reactor assembly 21 includes a stationary workbench or table 23 having a horizontal surface 25 thereon, a microwave power source 27, gas supply tanks 29, a vacuum pump 31, a programmable computer controller 33 and a reactor 35. An upstanding bracket 36 stationarily couples reactor 35 to surface 25. Reactor 35 has a plasma cavity 37 internal to a generally cylindrical and upstanding housing 39. An ignitor initiates plasma 40 in precursor reaction gases, such as H₂ and/or CH₄, from tanks 29, within cavity 37. The gas pressure within cavity 37 is about 1-100 Torr, and more preferably about 50-70 Torr, for gas flow of approximately 10 to 500 sccm.

Pressure gauges 41, power gauges 42, optionally temperature sensors and optionally valves 43, are electrically connected to controller 33 to allow for automated real-time adjustable control of the valves based in-part on output signals from the gauges and sensors. Controller 33 includes a microprocessor to run programmed software instructions stored in non-transient RAM or ROM memory, to receive input signals, compare the input signals to desired stored values, display output data, and optionally automatically send output signals to adjust the valves and associated plasma.

A hollow, quartz capillary tube 51 is elongated in a generally horizontal direction, substantially perpendicular to and intersecting housing 39 at cavity 37. The side arms of tube 51 and housing 39 define a generally+ (cross) shape. Tube 51 may be longer or shorter depending on the gas used and/or substrate size. However, it is preferred that the entire longitudinal length of tube from one side of housing 39 to the other, be longer than a total exterior length of housing 39 from its top to its bottom ends. For one example, a uniform internal diameter of tube 51 is 12.7 mm.

End caps 71 and 72 hold distal ends of tube 51 and include internal passages, and fittings or clamps, for coupling a gas inlet hose 73, pressure gauge 41 and pump outlet hose 75 thereto. Upstanding brackets 77 secure end caps 71 and 72 to surface 25. This embodiment reactor which includes housing 39 and tube 51, but excludes the gas tanks, microwave power supply, pump and controller, preferably has a maximum exterior dimension no greater than 20 cm³. This size and relatively simple mechanical structure advantageously allow for ease of assembly and disassembly, and a light weight and small size, thereby making it portable for transporting to different facilities, use in compact laboratory or manufacturing spaces, and of lower cost as compared to conventional CVD machines.

This reactor configuration serves as a 2.45 GHz microwave discharge cavity (cylindrical/pillbox cavity type) used to transfer the microwave power to the gas mixture, which is contained in the quartz tube acting as a vacuum chamber. An impedance matching stub 53 is used to match the impedance of the resonant cavity filled with conductive plasma medium to that of a coaxial line 55 of microwave power supply 27. The resonant frequency of this cavity is adjusted by a frequency tuning stub 57, and together with the impedance matching, power reflected from the cavity is minimized. In an example, the tubular side arms of the microwave cavity beneficially improve the coupling of the input power to the discharge, and reduce the tendency of arcing between the frequency and impedance matching stubs at optimum tuning conditions. Moreover, a fan 79 can be employed to externally air-cool reactor 35.

A workpiece holder 81 is a longitudinally elongated rod of approximately 3.18 mm diameter with spaced apart flats for holding multiple substrates or workpieces 83 thereon. A distal end of holder 81 is inserted into a sealed aperture of end cap 72, and linearly moved into an associated one of the side arms of tube 51. In one example, the holder is stainless steel. Holder 81 may be manually moved or automatically moved via an electromagnetic actuator, such as a stepper motor, solenoid or the like, controlled by controller 33. The present assembly and method may optionally move holder 81 and substrate(s) 83 thereon in linear and/or rotational directions while the plasma is within the reactor/cavity 35 and while the diamond layer is being grown upon the substrate. This in-process movement can beneficially create different diamond layer thicknesses across the substrate, if such a design is desired for a specific end use.

The leading substrate 83, located closest to the distal end of holder 81, is located within a cool zone Bin tube 51, which is about 5 cm long and spaced about 1 cm outward from cavity 40 internal to housing 39, shown as a spacing zone A which includes some of plasma 40 therein. Less than 100 W of microwave power is used to create a plasma within cavity 37 such that the deposition cool zone B is preferably 350-400° C., which is adjacent to but outside of the plasma cavity. Therefore, this temperature is ideally suited for growing a diamond layer of approximately 5-20 nm grain sizes upon a biomedical polymeric substrate, such as one made from at least one of: parylene, polyethylene, polyketone, polylactide, polyglycolide or the like, which can be subsequently implanted into a human or animal patient. In another configuration, one or more of the substrates 83 may be of a silicon material. Furthermore, each substrate may optionally have an exposed (to layering) surface area of at least 1 cm².

In one example using the present reactor assembly, a gas mixture of CH₄ and H₂ is used to ignite the plasma under following conditions:
Pressure: 1-60 Torr
Total Flow Rate: 10-500 sccm
Forward Power: 10-70 W
Reflected Power: 0-2 W
Volume % of CH₄ in total gas mixture: 5-20%.
Duration: 2-5 hrs
Substrate: intrinsic Si with and without surface pretreatment (which refers to scratching or seeding the substrate surface by ultrasonically attaching nanodiamond seeds to it in a nano-diamond aqueous solution for 2 minutes).

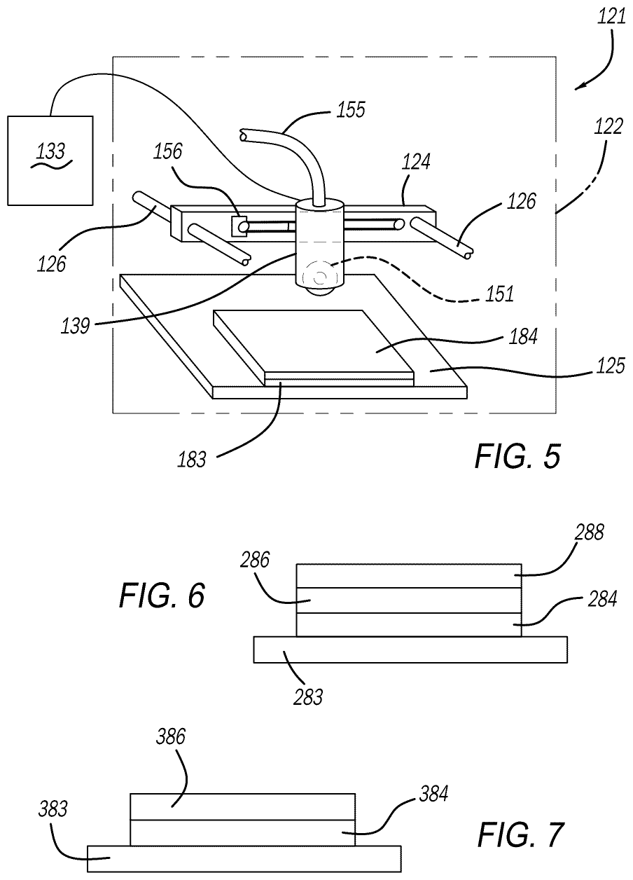

An alternate embodiment of a microwave capillary nanodiamond reactor assembly 121 is shown in FIG. 5. A sealed vacuum chamber or enclosure 122 has a bed or holder surface 125 on a floor thereof. One or more substrates or workpieces 183 are stationarily mounted upon surface 125. A gantry 124 spans above bed surface 125 within enclosure 122, and is slidable back and forth in longitudinal horizontal directions along outboard rails 126, driven by an electromagnetic or fluid powered actuator. A reactor head 139, having a partially-internal plasma cavity, and intersecting capillary tube 151, are movable in transverse horizontal directions along gantry 124. An electromagnetic or fluid powered actuator 156 drives a transmission, such as a cable or belt and pulley assembly to move reactor head 129 along the gantry. The reactive gases enter the capillary tube and microwave power is supplied to reactor head 139 via a cable 155. A programmable controller 133 automatically controls movement of the gantry, head, gas flow, pump, plasma and ignition.

The operating principle and structure are similar to that of the previous embodiment, however, plasma is emitted from an open end of reactor head 139 toward substrate 183. This creates diamond growth and layering 184 upon substrate 183. Notably, a large sized substrate (e.g., with a surface area greater than 1 cm² and more preferably greater than 10 cm²) can be processed with the present reactor head which is beneficially light weight, of small size and portable.

FIG. 6 shows a different workpiece configuration using any of the previously discussed reactor assemblies. A polymeric or silicon substrate 283 has a first diamond layer 284 directly grown thereon, and then a buffer of conductive or insulating layer 286 deposited thereon, and then a second diamond layer 288 grown on top of the buffer layer. The present reactor beneficially allows for an automatic controller-varied gas change during the plasma processing, without removal of the workpiece, to cause the different material layering.

Another different workpiece example, using any of the previously discussed reactor assemblies, can be observed with reference to FIG. 7. Here, a polymeric or silicon substrate 383 has a graphite layer 384 directly grown thereon, and then a diamond layer 286 is grown thereon. Additional layers may also be deposited. Again, the present reactor beneficially allows for an automatic controller-varied gas change during the plasma processing, without removal of the workpiece, to cause the different material layering. For example, methane plus argon for graphite layering and then methane plus hydrogen for diamond layering, may be used.

Another exemplary configuration provides a method for using a chemical vapor deposition flow through reactor, the method comprising: (a) supplying microwave power of less than 100 W to a cavity within the reactor; (b) creating a plasma within the cavity; (c) locating a workpiece within a zone in a hollow tube intersecting the cavity, the zone comprising at least one of: (i) a cool zone having an internal temperature no greater than 400° C. during step (b); or (ii) a hot zone having an internal temperature no greater than 1,000° C. during step (b); and (d) growing at least one of: a diamond or graphitic layer, on the workpiece within the zone.

While various embodiments have been disclosed, it should be appreciated that additional variations of the reactor and method are also envisioned. For example, different materials, layering combinations and gas combinations may be employed, however, some of the preferred benefits may not be obtained. Additional or different electrical hardware components may be used although certain of the present advantages may not be fully realized. While certain sizes and shapes have been disclosed it should be appreciated that alternate sizes and shapes may be used, although all of the present advantages may not be fully achieved. It is also noteworthy that any of the preceding features may be interchanged and intermixed with any of the others. Accordingly, any and/or all of the dependent claims may depend from all of their preceding claims and may be combined together in any combination. Variations are not to be regarded as a departure from the present disclosure, and all such modifications are entitled to be included within the scope and spirit of the present invention.

The invention claimed is:

1. A method for using a chemical vapor deposition flow through reactor, the method comprising:
(a) supplying microwave power of less than 100 W to a cavity within the reactor;
(b) creating a plasma within the cavity;
(c) locating a workpiece within a zone in a hollow tube intersecting the cavity, the zone comprising at least one of:
(i) a cool zone having an internal temperature no greater than 400° C. during step (b); or
(ii) a hot zone having an internal temperature no greater than 1,000° C. during step (b), the internal temperature of the hot zone being greater than that of the cool zone; and
(d) growing at least one of: a diamond or graphitic layer, on the workpiece within the zone.

2. The method of claim 1, further comprising depositing at least a second layer on the diamond or graphitic layer, in the reactor, the second layer being of a different material than the diamond or graphitic layer.

3. The method of claim 2, further comprising depositing at least a third layer on the second layer in the reactor, the third layer being of a different material than the second layer.

4. The method of claim 1, further comprising moving the workpiece within the tube during the plasma creation in order to vary a characteristic of the growing step.

5. The method of claim 1, further comprising using a gantry to move a plasma generating head, which includes the cavity, relative to the workpiece during the plasma creation and the growing steps.

6. The method of claim 1, further comprising using a programmable controller to automatically adjust the plasma based on sensor signals.

7. The method of claim 1, wherein the workpiece is located in the cool zone, spaced outward from the cavity, during the growing step.

8. The method of claim 1, further comprising causing the diamond layer to have 5-20 nm grain size grown upon the workpiece, which is polymeric, and the workpiece having a surface area of at least 1 cm² upon which the diamond layer is grown.

9. The method of claim 1, further comprising causing the diamond layer to have 5-20 nm grain size grown upon the workpiece, which is silicon, and the workpiece having a surface area of at least 1 cm² upon which the diamond layer is grown.

10. A method for using a chemical vapor deposition flow through reactor, the method comprising:
(a) supplying microwave power of less than 100 W to a cavity within the reactor;
(b) creating a plasma within the cavity;
(c) locating a substrate within a cool zone in a hollow tube intersecting the cavity, the cool zone having an internal temperature no greater than 400° C. during step (b); and
(d) growing a diamond layer on the substrate within the cool zone.

11. The method of claim 10, further comprising depositing at least a second layer on the diamond or graphitic layer, in the reactor, the second layer being of a different material than the diamond or graphitic layer.

12. The method of claim 11, further comprising depositing at least a third layer on the second layer in the reactor, the third layer being of a different material than the second layer.

13. The method of claim 10, further comprising moving the substrate within the tube during the plasma creation in order to vary a characteristic of the growing step.

14. The method of claim 10, further comprising using a gantry to move a plasma generating head, which includes the cavity, relative to the substrate during the plasma creation and the growing steps.

15. The method of claim 10, further comprising causing the diamond layer to have 5-20 nm grain size grown upon the workpiece, which is polymeric, and the workpiece having a surface area of at least 1 cm² upon which the diamond layer is grown.

16. The method of claim 10, further comprising causing the diamond layer to have 5-20 nm grain size grown upon the workpiece, which is silicon, and the workpiece having a surface area of at least 1 cm² upon which the diamond layer is grown.

17. A method for using a chemical vapor deposition flow through reactor, the method comprising:
(a) supplying microwave power to a cavity within the reactor;
(b) creating a plasma within the cavity;
(c) moving at least one of: a substrate or the cavity, relative to the other during step (b); and
(d) growing at least one of: a diamond layer or a graphite layer on the substrate.

18. The method of claim 17, further comprising depositing at least a second layer on the diamond or graphitic layer, in the reactor, the second layer being of a different material than the diamond or graphitic layer.

19. The method of claim 17, wherein the moving step comprises moving the substrate within a hollow tube coupled to the cavity during the plasma creation in order to vary a characteristic of the growing step, and a temperature within the hollow tube being no greater than 400° C. during the plasma creation.

20. The method of claim 17, wherein the moving step comprises using a gantry to move a plasma generating head, which includes the cavity, relative to the substrate during the plasma creation and the growing steps.

21. A chemical vapor deposition flow through reactor apparatus comprising:
(a) a reactor cavity;
(b) a microwave power supply configured to supply microwave power of less than 100 W to the reactor cavity;
(c) a precursor reaction gas being supplied to the cavity, wherein the microwave power and gas are configured to create a plasma within the cavity;
(d) a substrate located within a zone adjacent to the cavity, the zone comprising at least one of:
(i) a cool zone having an internal temperature no greater than 400° C. during plasma creation; or
(ii) a hot zone having an internal temperature no greater than 1,000° C. during plasma creation, the internal temperature of the hot zone being greater than that of the cool zone; and
(e) an actuator moving at least one of the substrate and the cavity relative to the other during creation at least one of: a diamond or graphitic layer, on the substrate within the zone.
